(19) United States
(12) Patent Application Publication
(10) Pub. No.: US 2014/0370439 A1
(43) Pub. Date: Dec. 18, 2014

(54) METHODS AND SYSTEMS FOR REDUCING BUBBLES IN LAYERS OF PHOTORESIST MATERIAL

(71) Applicant: GLOBALFOUNDRIES Inc., Grand Cayman (KY)

(72) Inventors: Kurt Hollis, Saratoga Springs, NY (US); Michael Van Tassel, Burnt Hills, NY (US)

(21) Appl. No.: 13/918,456

(22) Filed: Jun. 14, 2013

(51) Int. Cl. G03F 7/004; B01D 33/03

(52) U.S. Cl. CPC G03F 7/004; B01D 33/03
USPC 430/270.1; 210/388

(57) ABSTRACT

One illustrative system disclosed herein includes a tank adapted to hold a fluid, a photoresist filter adapted to receive the fluid and allow the fluid to flow through the filter, and a vibrator that is operatively coupled to the photoresist filter and adapted to vibrate the photoresist filter as the fluid flows through the photoresist filter. A method disclosed herein includes forcing a fluid through a photoresist filter and actuating a vibrator so as to vibrate the photoresist filter while the fluid is flowing through the photoresist filter.

### BACKGROUND OF THE INVENTION

1. Field of the Invention

The present disclosure generally relates to the fabrication of integrated circuits, and, more particularly, to various methods and systems for reducing bubble formation in a layer of photoresist material.

2. Description of the Related Art

The fabrication of advanced integrated circuits, such as CPU's, storage devices, ASIC's (application specific integrated circuits) and the like, requires the formation of a large number of circuit elements in a given chip area according to a specified circuit layout, wherein so-called metal oxide semiconductor field effect transistors (MOSFETs or FETs) represent one important type of circuit element that substantially determines performance of the integrated circuits. The transistors are typically either NMOS (NFET) or PMOS (PFET) type devices wherein the “N” and “P” designation is based upon the type of dopants used to create the source/drain regions of the devices. So-called CMOS (Complementary Metal Oxide Semiconductor) technology or products refers to integrated circuit products that are manufactured using both NMOS and PMOS transistor devices.

Field effect transistors, whether an NMOS or a PMOS device, typically include a source region, a drain region, a channel region that is positioned between the source region and the drain region, and a gate electrode positioned above the channel region. Current flow through the FET is controlled by controlling the voltage applied to the gate electrode. For an NMOS device, if there is no voltage (or a logically low voltage) applied to the gate electrode, then there is no current flow through the device (ignoring undesirable leakage currents, which are relatively small). However, when an appropriate positive voltage (or logically high voltage) is applied to the gate electrode, the channel region of the NMOS device becomes conductive, and electrical current is permitted to flow between the source region and the drain region through the conductive channel region. For a PMOS device, the control voltages are reversed. Field effect transistors may come in a variety of different physical shapes, e.g., so-called planar FET devices or so-called 3-D or FinFET devices.

In general, the formation of integrated circuit products involves performing a detailed sequence, i.e., a detailed process flow, of many different process operations, such as, for example, deposition processes, etching processes, ion implantation processes, chemical mechanical polishing (CMP) processes, photolithography processes, heating processes, etc., to manufacture the device. Such process operations are performed, more or less, on a layer-by-layer basis until the device is completed. As indicated, photolithography is one of the basic processes used in manufacturing integrated circuit products. A typical photolithography process generally involves the steps of: (1) applying a layer of photoresist material above a wafer, typically accomplished by a spin-coating process; (2) pre-baking (or soft-baking) the layer of photoresist at a temperature of approximately 90-120° C. to reduce the level of solvents in the layer of photoresist and to improve the adhesion characteristics of the photoresist; (3) performing an exposure process, wherein a so-called “stepper tool” is used to project a pattern defined in a reticle onto the layer of photoresist to thereby create a latent image of the reticle pattern in the layer of photoresist; (4) performing a post-exposure bake process on the layer of photoresist at a temperature approximately 5-15° C. higher than the pre-bake process; (5) performing a so-called “develop” process to turn the latent image in the layer of photoresist into the final resist image; and (6) performing a post-bake process (or hard-bake) at a temperature of approximately 125-160° C. to remove residual solids and to improve adhesion of the patterned photoresist mask layer. These process steps are well known to those skilled in the art and, thus, will not be described herein in any greater detail. Various process operations, such as etching or ion implantation processes, may then be performed on an underlying layer of material or substrate through the patterned photoresist mask layer.

FIG. 1 is a schematic and simplistic depiction of a prior art system 10 that is typically used to deliver and deposit a quantity of a photoresist material on an illustrative wafer. In general, the system 10 is comprised of a photoresist tank 12 that contains a photoresist material 14, a pump 13, a filter assembly 16, a dispensing nozzle 18, a rotatable wafer chuck 20 and an illustrative wafer or substrate 22 that is adapted to have a layer of photoresist material formed thereon. The filter assembly 16 generally includes a filter housing 17 that contains an internal filter 19. Of course, as will be recognized by those skilled in the art, the system 10 depicted in FIG. 1 contains many additional features and components that are not shown in FIG. 1, e.g., vent lines, control valves, pumps, etc. In operation, the pump 13 provides the energy to drive the photoresist material 14 through the system 10. Photoresist material 14 is supplied to the pump 13 via a tank outlet 12A, where it is pressurized and introduced into the filter housing 17 via a filter assembly inlet 16A. Typically, the filter housing 17 is large enough in size so that, when the pressurized photoresist material enters the filter housing 17, the pressure of the pressurized photoresist material will be reduced, thereby allowing at least some of any dissolved gases in the photoresist material 14 to escape and be vented from the filter hosing 17 via a vent line (not shown). Typically, the filter 19 within the filter housing 17 is comprised of an outer canister that contains a number of small openings and an internal filter medium positioned within the canister. Typically, the filter medium used in modern photolithography tools is comprised of a nylon or ultra-high molecular weight polyethylene (UPE) membrane. In general, in the depicted example, the incoming photoresist material 14 is forced through the openings in the canister and out through the filter medium where it exits the filter assembly 16 via filter exit 16B as, hopefully, a clean photoresist material 14C. Thereafter, with the chuck 22 spinning the wafer 20, the clean photoresist material 14C is deposited on the rotating wafer via the nozzle 18. Typically, the quantity of photoresist material deposited on the wafer is very tightly controlled in an effort to produce uniform layers of photoresist materials on the wafers as thousands of wafers are processed in manufacturing integrated circuit products.

However, as noted above, in recent years, device dimensions and pitches have been greatly reduced in size, thereby requiring even further precision when manufacturing such devices. The requirement for increased precision in manufacturing applies to all aspects of the semiconductor manufacturing process, including the formation of very accurate layers of photoresist material and ultimately accurate photoresist masks. Thus, the presence of even small particles in the photoresist material layer that is formed on the wafer 22 can result in errors when forming the features of an integrated circuit product. That is why device manufacturers go to great lengths in an effort to insure that, to the extent possible, the photoresist material 14 deposited on the wafer 22 is free of foreign particles.

However, the presence of foreign particles in the photoresist material 14 is not the only problem faced by device manufacturers. The presence of bubbles of gas in the photoresist material 14 that is deposited on the wafer 22 can also cause problems, such as undesirable thickness variations, pin-holes, high particle counts, etc. Manufacturers typically try to remove most, if not all, gases that are dissolved in the photoresist material 14 by flashing and venting the photoresist material 14. One significant problem arises with bubble formation when the filter 19 has to be changed. In general, due to the nature of the filter medium, gas is trapped in a new filter. Accordingly, the new filter must be “conditioned” in an effort to try to eliminate some or all of the bubbles produced by the new filter before the new filter can be used when forming layers of photoresist material 14 on actual production wafers so as not to increase the chance of producing defective integrated circuit products.

Typically, the filter conditioning process recommended by at least one manufacturer of photolithography tools involves performing an initial “soaking” period followed by performing several “purge” operations until such time as testing reveals that the new filter is acceptable for production activities. The initial soaking process typically involves placing the new filter in a liquid, such as propylene glycol methyl ether acetate (sometimes referred to as EBR-73 that is used in edge bead removal processes), for an extended period of time, e.g., 10-12 hours. After the soaking process is completed, then multiple “purges”, e.g., typically about 2-3 in number, are conducted wherein significant quantities of photoresist material and/or propylene glycol methyl ether acetate is forced, under relatively high pressure, e.g., 40 psi, through the new filter. This purging process is continued until such time that bubbles produced by the new filter are eliminated or at least reduced in quantity to an acceptable level. For example, in some cases, such conditioning of a new filter may take up to 12 hours and may involve the use of about 4 liters of photoresist material. In addition to slowing down the manufacturing process, the conditioning of new filters using such techniques is very expensive as the photoresist material/propylene glycol methyl ether acetate used in conditioning the new filter is relatively expensive.

The present disclosure is directed to various methods and systems for reducing bubble formation in a layer of photoresist material that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods and systems for reducing bubble formation in a layer of photoresist material. One method disclosed herein includes forcing a fluid through a photoresist filter and actuating a vibrator so as to vibrate the photoresist filter while the fluid is flowing through the photoresist filter.

One example of an illustrative system disclosed herein includes a tank adapted to hold a fluid, a photoresist filter adapted to receive the fluid and allow the fluid to flow through the filter, and a vibrator that is operatively coupled to the photoresist filter and adapted to vibrate the photoresist filter as the fluid flows through the photoresist filter

Another illustrative example of a novel system disclosed herein includes a tank adapted to hold a photoresist material, a photoresist filter adapted to receive the photoresist material and allow the photoresist to flow through the filter, and a vibrator that is operatively coupled to the photoresist filter and adapted to vibrate the photoresist filter as photoresist material flows through the photoresist filter.

### BRIEF DESCRIPTION OF THE DRAWINGS

The disclosure may be understood by reference to the following description taken in conjunction with the accompanying drawings, in which like reference numerals identify like elements, and in which:

FIG. 1 is a schematic and simplistic depiction of a prior art system that is used to deliver and deposit a quantity of photoresist material on an illustrative wafer;

FIG. 2 is a schematic depiction of one illustrative system disclosed herein;

FIG. 3 is an image of one illustrative embodiment of a vibrator that may be employed with the methods and systems described herein; and

FIG. 4 is a schematic depiction of another illustrative system disclosed herein.

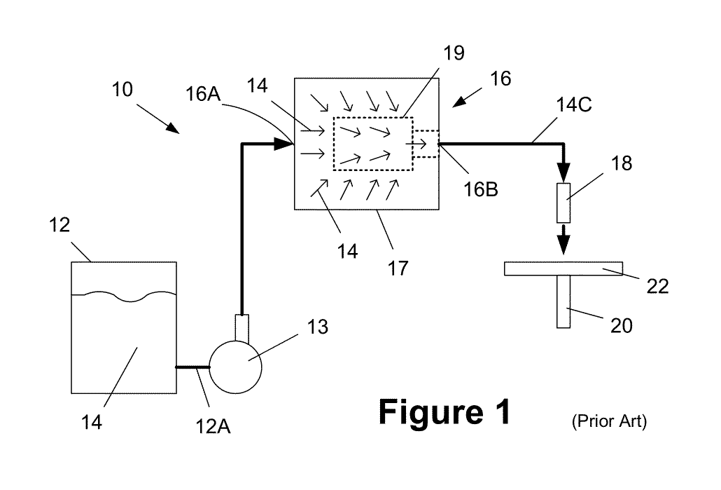

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure generally relates to various methods and systems for reducing bubble formation in a layer of photoresist material. Moreover, as will be readily apparent to those skilled in the art upon a complete reading of the present application, the methods and systems disclosed herein may be employed in forming patterned photoresist masking layers that may be used when forming many aspects or features of a variety of different devices, including, but not limited to, logic devices, memory devices, etc. With reference to the attached figures, various illustrative embodiments of the methods and systems disclosed herein will now be described in more detail.

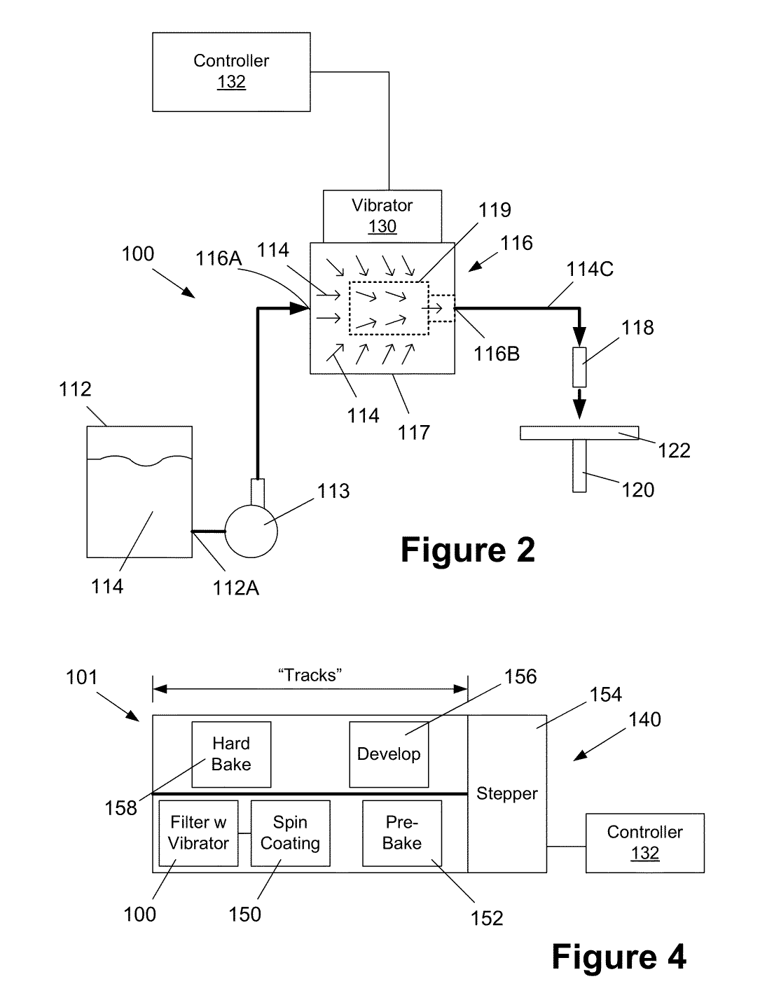

FIG. 2 is a schematic and simplistic depiction of a novel system 100 disclosed herein that may be used to deliver and deposit a quantity of a photoresist material on an illustrative wafer. In general, the system 100 is comprised of a photoresist tank 112 that contains a photoresist material 114, a pump 113, a filter assembly 116, a vibrator device or mechanism 130, a controller 132, a dispensing nozzle 118, a rotatable wafer chuck 120 and an illustrative wafer or substrate 122 that is adapted to have a layer of photoresist material formed thereon. The filter assembly 116 generally includes a filter housing 117 that contains an internal filter 119. Of course, as will be recognized by those skilled in the art, the system 100 depicted in FIG. 2 contains many additional features and components that are not shown in FIG. 2, e.g., vent lines, control valves, etc. In operation, the pump 113 provides the energy to drive the photoresist material 114 through the system 100. Of course, other means of driving the photoresist material through the system 100 may be employed as well, e.g., a source of pressurized gas, such as nitrogen. Photoresist material 114 is supplied to the pump 113 via a tank outlet 112A, where it is pressurized and introduced into the filter housing 117 at a filter assembly inlet 116A. Typically, the filter housing 117 is large enough in size so that, when the pressurized photoresist material 114 enters the filter housing 117, the pressure of the pressurized photoresist material 114 will be reduced, thereby allowing at least some of any dissolved gases in the photoresist material 114 to escape and be vented from the filter housing 117 via a vent line (not shown). Typically, the filter 119 within the filter housing 117 is comprised of an outer canister (not shown) that contains a number of small openings and an internal filter medium positioned within the canister. Typically, the filter medium used for the filter 119 in modern photolithography tools is comprised of a nylon or ultra-high molecular weight polyethylene (UPE). However, as will be appreciated by those skilled in the art after a complete reading of the present application, the methods and systems disclosed herein may be employed with a variety of different photoresist filters 119 that have a variety of different physical configurations that may use a variety of different filter mediums. Thus, the presently disclosed inventions should not be considered to be limited to any particular type of photoresist filter or for use with any particular type of photolithography tool.

In general, in the depicted example, the incoming photoresist material 114 is forced through the openings in the filter 119 canister and out through the filter medium where it exits the filter 119 via the filter assembly exit 116B as a clean photoresist material 114C. Thereafter, with the chuck 122 spinning the wafer 120, the clean photoresist material 114C is deposited on the rotating wafer 120 via the nozzle 118. Typically, the quantity of photoresist material deposited on the wafer is very tightly controlled in an effort to produce uniform layers of photoresist materials on the wafers as thousands of wafers are processed in manufacturing integrated circuit products.

Unlike the prior art systems disclosed in the background section of this application, the methods and systems disclosed herein involve, among other things, forcing a fluid through the filter medium in the filter 119 while causing the filter 119 to be vibrated. In the depicted example, the means of causing such vibrations is the schematically depicted vibrator 130. The vibrations may be generated continuously or intermittently, and the frequency of the vibrations may vary depending upon the particular application. The size and power of the vibrator 130 may also vary depending upon the particular application. In the depicted example, the vibrator 130 may be actuated and controlled by the schematically depicted controller 132. In other cases, the vibrator 130 may be actuated manually as needed.

In general, the vibrator 130 may be operatively coupled to the filter 119 in a variety of different ways such that, when the vibrator 130 is actuated, the filter 119 experiences the desired vibrations. The vibrator 130 may be directly or indirectly coupled to the filter 119 so as to achieve this objective. In the depicted example, the vibrator 130 may be removably coupled to the filter housing 117 in such a manner so as to cause the desired vibration of the filter 119 when the vibrator 130 is actuated. For example, the vibrator 130 may be bolted or strapped to the filter housing 117. Of course, after a complete reading of the present application, those skilled in the art will recognize that the vibrator 130 may be operatively coupled to the filter 119 using a variety of different ways and techniques so as to enable the vibrator 130 to cause the desired vibrations in the filter 119.

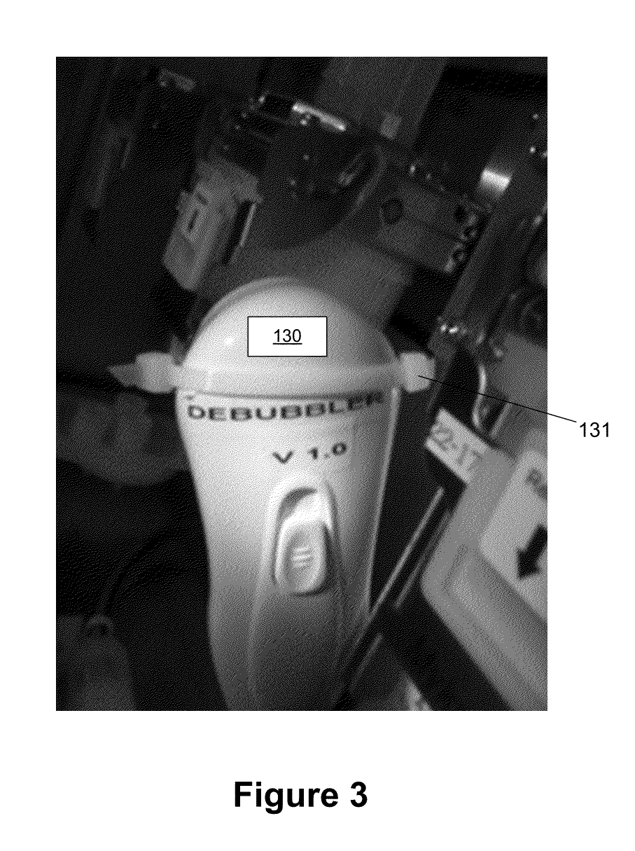

The vibrator 130 may take a variety of forms but, in general, it is adapted to generate vibrations using any known structure or means for generating vibrations. For example, in one embodiment, the means for generating such vibrations may be an electric motor positioned within the vibrator 130 that includes an unbalanced mass on the driveshaft of the electric motor. Other means of generating vibrations are well known to those skilled in the art, e.g., pulsating pistons or diaphragms, etc. In one illustrative embodiment, the vibrator 130 may be an electrically-powered device, but it may also be a pneumatically-powered or fluid-powered vibrator, etc. In one particular embodiment, the vibrator 130 disclosed herein may comprise an electric motor. The frequency of the vibrations generated by the vibrator 130 may also vary depending upon the particular application. FIG. 3 depicts one illustrative embodiment of a vibrator 130 that was employed in performing the testing below. In this example, the device used as the vibrator 130 was a commercially available wave face scrubber (sold by Neutrogena) that was operatively coupled to the filter housing 119 (not clearly seen in FIG. 3) by means of a plurality of plastic zip ties 131.

FIG. 4 depicts an illustrative example of another system 101 where the system 100 may be employed so as to form patterned photoresist masking layers on semiconductor substrates. FIG. 4 is a schematic and simplistic depiction of an illustrative photolithography tool 140 that may be found in many semiconductor manufacturing facilities. In general, the system 101 is comprised of spin-coating station 150, a pre-bake section 152, a stepper section 154, a develop station 156 and a hard-bake station 158. The portions of the system 101 other than the stepper section 154 are sometimes referred to as “tracks” given the flow of wafers as they move through the photolithography tool 140. The functions performed at each of these stations are well known to those skilled in the art. In the depicted example, the system 100 is operatively coupled to the spin-coating station 150. In this embodiment, the above-described controller 132 may be a general purpose computer that is adapted to control all of the functions performed by the system 101. As described more fully below, the system 100 may be employed in production equipment, such as in the illustrative photolithography tool 140, or it may implemented within a fabrication facility as a stand-alone system that is used to condition new filters 119 before they are placed in service. Thus, it is not required that the system 100 be part of actual production equipment, although such a configuration may be frequently employed.

In contrast to the time-consuming filter conditioning processes described in the background section of this application, the inventors have discovered that, by vibrating the filter 119 as a fluid is being forced through the filter 119, the number of bubbles or defects that appear in the resulting deposited layer of photoresist material can be significantly reduced and it may be accomplished much cheaper and much faster than can be accomplished using the prior art methods.

In one set of testing (“EBR testing), a brand new 5 nm filter 119 (made by Mycrolis) was positioned in the system 101. Four test wafers were involved in this part of the testing. The four wafers were inspected before the testing began to determine the presence of defects that existed on the surface of the test wafers prior to the formation of a layer of photoresist material. Thereafter, about 300 ml of propylene glycol methyl ether acetate was flushed through the filter 119 at a relatively low pressure, e.g., 5-15 psi, using the standard photoresist pumping equipment that is resident on the photolithography tool 140. After the EBR-cleaning process was completed, about 175 “dummy dispense” operations were performed wherein the photoresist material was simply discarded. The latter 75 of these dummy dispense operations was performed in an effort to remove as much air as possible from the system. During the first 100 of the dummy dispense operations, the filter 119 was subjected to continuous vibrations that were produced by the vibrator 130 during each dispense cycle. The vibrator 130 was not actuated during the last 75 of the above-noted dummy dispense operations. Thereafter, a layer of photoresist material was formed on each of the four test wafers and the number of defects present in the layer of photoresist material was determined. The chart below shows that the number of bubbles or defects in the resulting layers of photoresist was very low and acceptable for production. Additionally, the estimated quantity of the propylene glycol methyl ether acetate and the photoresist material consumed during this testing/qualification process was relatively low, e.g., about 300 ml of the propylene glycol methyl ether acetate and about 200 ml of the photoresist material. Note that, in this round of EBR testing, the new filter 119 was not subjected to the prior art “soaking” process or any of the relatively high-pressure “purges” described in the background section of this application.

EBR Liquid Cleaning

| | | Number of Defects | |
|---|---|---|---|
| | Number of Defects | present in photoresist | |
| Wafer # | on Starting Wafer | layer | Filter Vibrated? |
| 1 | 6 | 9 | Yes |
| 2 | 5 | 7 | Yes |
| 3 | 15 | 14 | Yes |
| 4 | 3 | 6 | Yes |

In another set of testing (MIBC testing), an existing 5 nm filter 119 was in place in the system 101. Two test wafers were involved in this part of the testing. As before, the two wafers were inspected before the testing began to determine the presence of defects that existed on the test wafers prior to the formation of a layer of photoresist material. This testing involved using MIBC (Methyl isobutyl carbinol) to clean the filter 119. About 100 ml of MIBC was flushed through the filter 119 at a relatively low pressure, e.g., 5-15 psi, using the standard photoresist pumping equipment that is resident on the photolithography tool 140. After the MIBC-cleaning process was completed, about 100 dummy dispense operations were performed wherein the photoresist material was simply discarded and wherein the filter 119 was subjected to continuous vibrations that were produced by the vibrator 130 during each dispense cycle. Then, about another 150 of these dummy dispense operations was performed in an effort to remove as much air as possible from the system. The vibrator 130 was not actuated during these latter 150 dummy dispense operations. Thereafter, a layer of photoresist material was formed on each of the two test wafers and the number of defects present in the layer of photoresist material was determined. The hard particle count (i.e., defects) for the two layers of photoresist material was dramatically reduced to 450 and 697—an order of magnitude decrease in defects due to the use of the methods and systems disclosed herein. Among other things, this MIBC testing demonstrates the utility of the present inventions goes beyond that of merely conditioning new filters. Additionally, the estimated quantity of MIBC and the photoresist material consumed during this MIBC testing process was relatively low, e.g., about 100 ml of MIBC and about 200 ml of the photoresist material. Note that, in this round of MIBC testing, the filter 119 was not subjected to the prior art “soaking” process or any of the relatively high-pressure “purges” described in the background section of this application.

MIBC Liquid Cleaning

| | | Number of Defects | |
|---|---|---|---|
| | Number of Defects | present in photoresist | |
| Wafer # | on Starting Wafer | layer | Filter Vibrated? |
| 1 | 34 | 6180 | No |
| 1 | 33 | 5667 | No |
| 2 | 26 | 697 | Yes |
| 2 | 26 | 465 | Yes |

Another set of testing (“No Soak” testing) was performed to determine what impact, if any, not performing the manufacturer recommended soaking period for a new filter might have on the cleanliness of the resulting photoresist layers when using the methods disclosed herein. A new 5 nm filter 119, which had not been subjected to any soaking process, was the subject of these tests. Six test wafers were involved in this part of the testing. As before, the six wafers were inspected before the testing began to determine the presence of defects that existed on the test wafers prior to the formation of a layer of photoresist material. For wafers 1 and 2, a layer of photoresist material was formed on these wafers after the system was flushed using about 300 ml of propylene glycol methyl ether acetate with only the flushing shell in position in the tool, i.e., the filter 119 was not positioned in the tool, and after purging the system was performed using best known methods. Thereafter, the new filter 119 was installed in the tool, the photoresist tank was vented for about 45 seconds and the filter 119 was vented for about 25 seconds. The vibrator 130 was attached to the filter housing 117 at this point. At this point, about 100 dummy dispense operations were performed wherein the photoresist material was simply discarded and wherein the filter 119 was subjected to continuous vibrations that were produced by the vibrator 130 during each dispense cycle. Then, about another 75 of these dummy dispense operations was performed in an effort to remove as much air as possible from the dispensed photoresist material. The vibrator 130 was not actuated during these latter 75 dummy dispense operations. Thereafter, a layer of photoresist material was formed on each of wafers 3 and 4 and the number of defects present in the layer of photoresist material was determined. Prior to forming layers of photoresist on wafers 5 and 6, about 50 more dummy dispense operations were performed. During these latter 50 dummy dispense operations, the filter 119 was not vibrated. Thereafter, a layer of photoresist material was formed on each of wafers 5 and 6 and the number of defects present in the layer of photoresist material was determined. Additionally, the estimated quantity of propylene glycol methyl ether acetate and the photoresist material consumed during this “No-Soak” testing/qualification process was relatively low, e.g., about 300 ml of propylene glycol methyl ether acetate and about 300 ml of the photoresist material. Note that, in this round of “No-soak” testing, the filter 119 was not subjected to the prior art “soaking” process or any of the relatively high-pressure “purges” described in the background section of this application. Typically, to qualify a new filter using propylene glycol methyl ether acetate, the particles in the resulting layer of photoresist should be less than 50 particles. The testing below indicates that defects in the layers formed on wafers 5 and 6 did not quite reach that level. It is believed that if additional dummy dispense cycles (without vibration), e.g., if about 25-50 additional dummy dispense cycles were performed, the number of defects in the layers of photoresist material would have likely fallen below this 50 particle limitation. However, and importantly, all of the above-described “no-soak” testing only took one hour to complete—much less than the 12 hour soak period for new filters recommended by some photolithography tool manufacturers.

“No-Soak” Testing

| | | Number of Defects | |
|---|---|---|---|
| | Number of Defects | present in photoresist | |
| Wafer # | on Starting Wafer | layer | Filter Vibrated? |
| 1 | 1 | 1830 | No-filter not |
| | | | present |
| 2 | 4 | 1877 | No-filter not |
| | | | present |
| 3 | 3 | 85 | Yes |
| 4 | 0 | 88 | Yes |
| 5 | 1 | 59 | Yes |
| 6 | 2 | 58 | Yes |

As will be recognized by those skilled in the art after a complete reading of the present application, the methods and systems disclosed herein provide many benefits to a semiconductor manufacturer. For example, the inventions disclosed herein may be employed to condition photoresist filters much faster than was possible using the manufacturers' recommended processes described in the background section of this application. This may reduce production down-time, a critical issue in manufacturing integrated circuit products. Additionally, by employing the inventions disclosed herein, semiconductor manufacturers may save significant sums of money by avoiding the excessive waste of cleaning fluids and photoresist materials that was common using the manufacturers' recommended processes described in the background section of this application. Lastly, as noted above, the inventions disclosed herein may be employed in production equipment and/or used on a regular basis or they may only be employed in conditioning new photoresist filters. Other advantages will be recognized by those skilled in the art after a complete reading of this application.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A system, comprising:
a tank adapted to hold a fluid;
a photoresist filter adapted to receive said fluid and allow said fluid to flow through said filter; and
a vibrator that is operatively coupled to said photoresist filter and adapted to vibrate said photoresist filter as said fluid flows through said photoresist filter.

2. The system of claim 1, wherein said photoresist filter is positioned within a filter housing and wherein said vibrator is operatively coupled to said filter housing.

3. The system of claim 2, wherein said vibrator is attached to said filter housing.

4. The system of claim 1, wherein said vibrator comprises an electric motor.

5. The system of claim 1, wherein said vibrator is adapted to continuously vibrate said photoresist filter.

6. The system of claim 1, wherein said vibrator is adapted to intermittently vibrate said photoresist filter.

7. The system of claim 1, wherein said fluid is one of a photoresist material, MIBC or propylene glycol methyl ether acetate.

8. The system of claim 1, wherein said photoresist filter is a new photoresist filter.

9. A system, comprising:
a tank adapted to hold a photoresist material;
a photoresist filter adapted to receive said photoresist material and allow said photoresist material to flow through said photoresist filter; and
a vibrator that is operatively coupled to said photoresist filter and adapted to vibrate said photoresist filter as photoresist material flows through said photoresist filter.

10. The system of claim 9, wherein said photoresist filter is positioned within a filter housing and wherein said vibrator is operatively coupled to said filter housing.

11. The system of claim 10, wherein said vibrator is attached to said filter housing.

12. The system of claim 9, further comprising:
a wafer chuck that is adapted to rotate a wafer; and
a dispensing nozzle that is adapted to receive and dispense a quantity of said photoresist material after it has passed through said photoresist filter.

13. The system of claim 9, further comprising a pump that is adapted to receive said photoresist material from said tank and transfer said photoresist material to said photoresist filter.

14. The system of claim 9, wherein said vibrator is adapted to continuously vibrate said photoresist filter.

15. The system of claim 9, wherein said vibrator is adapted to intermittently vibrate said photoresist filter.

16. The system of claim 9, wherein said photoresist filter is a new photoresist filter.

17. A method, comprising:
forcing a fluid through a photoresist filter; and
actuating a vibrator so as to vibrate said photoresist filter while said fluid is flowing through said photoresist filter.

18. The method of claim 17, wherein actuating said vibrator comprises actuating a vibrator that is operatively coupled to a filter housing that has said photoresist filter positioned therein.

19. The method of claim 17, wherein actuating said vibrator comprises turning on an electric motor.

20. The method of claim 17, wherein actuating said vibrator comprises actuating said vibrator so as to continuously vibrate said photoresist filter as said fluid flows through said photoresist filter.

21. The method of claim 17, wherein actuating said vibrator comprises actuating said vibrator so as to intermittently vibrate said photoresist filter as said fluid flows through said photoresist filter.

22. The method of claim 17, wherein said fluid is one of a photoresist material, MIBC or propylene glycol methyl ether acetate.

23. The method of claim 17, wherein said photoresist filter is a new photoresist filter.

24. A method, comprising:
forcing a photoresist material through a photoresist filter; and
actuating a vibrator so as to vibrate said photoresist filter while photoresist material is being forced through said photoresist filter.

25. The method of claim 24, wherein actuating said vibrator comprises actuating a vibrator that is operatively coupled to a filter housing that has said photoresist filter positioned therein.

26. The method of claim 24, wherein actuating said vibrator comprises actuating said vibrator so as to continuously vibrate said photoresist filter as said photoresist material is forced through said photoresist filter.

27. The method of claim 24, wherein actuating said vibrator comprises actuating said vibrator so as to intermittently vibrate said photoresist filter as said photoresist material is forced through said photoresist filter.

28. The method of claim 24, wherein forcing said photoresist material through said photoresist filter comprises pumping said photoresist material through said photoresist filter.
